(19) United States
(12) Patent Application Publication
(10) Pub. No.: US 2021/0313294 A1
(43) Pub. Date: Oct. 7, 2021

(54) SEMICONDUCTOR PACKAGE AND METHOD FOR FABRICATING THE SAME

(71) Applicant: Infineon Technologies AG, Neubiberg (DE)

(72) Inventors: Chau Fatt Chiang, Melaka (MY); Xavier Arokiasamy, Teluk Intan (MY); Naveendran Chellamuthu, Melaka (MY); Chee Chiew Chong, Batu Caves (MY); Joo Ming Goa, Batu Pahat Johor (MY); Chee Hong Lee, Melaka (MY); Muhammat Sanusi Muhammad, Melaka (MY); Chee Voon Tan, Seremban (MY); Wee Boon Tay, Melaka (MY)

(21) Appl. No.: 17/210,693

(22) Filed: Mar. 24, 2021

(30) Foreign Application Priority Data
Apr. 7, 2020 (DE) 102020109703.4

(51) Int. Cl. H01L 23/00; H01L 21/48; H01L 23/495

(52) U.S. Cl. CPC H01L 24/40; H01L 2224/40139; H01L 23/49524; H01L 24/32; H01L 24/33; H01L 24/35; H01L 24/37; H01L 24/84; H01L 24/83; H01L 24/92; H01L 24/97; H01L 23/49548; H01L 23/49513; H01L 2224/84947; H01L 2224/84815; H01L 2224/32245; H01L 2224/33181; H01L 2224/37012; H01L 2224/37011; H01L 2224/40475; H01L 2224/92246; H01L 2224/95136; H01L 2224/9211; H01L 2224/83192; H01L 2224/83193; H01L 2224/83815; H01L 2224/9221; H01L 2224/9205; H01L 2224/40095; H01L 2224/4007; H01L 2224/40245; H01L 2224/35847; H01L 2224/97; H01L 2224/40101; H01L 2224/40137; H01L 21/4842

(57) ABSTRACT

A semiconductor package includes a carrier having a recess, a semiconductor die arranged on the carrier such that a first side of the semiconductor die faces the carrier, and a contact clip arranged over a second side of the semiconductor die, opposite the first side. The contact clip includes a lowered part. The lowered part is arranged in the recess.

### TECHNICAL FIELD

This disclosure relates in general to semiconductor packages and to methods for fabricating semiconductor packages.

### BACKGROUND

Semiconductor packages may comprise different components which have to be stacked on top of each other during fabrication. Examples for such components are carriers, semiconductor dies and contact clips. In a stage of fabrication before joints that keep these stacked components in place have been cured, the stacked components may shift. For example, a contact clip placed onto a solder deposit may shift while the solder material is fluid. Furthermore, arranging these components on top of each other may be a time consuming process which may significantly impact overall fabrication time and fabrication costs. Improved semiconductor packages and improved methods for fabricating semiconductor packages may help with solving these and other problems.

The problem on which the invention is based is solved by the features of the independent claims. Further advantageous examples are described in the dependent claims.

### SUMMARY

Various aspects pertain to a semiconductor package, comprising: a carrier comprising a recess, a semiconductor die arranged on the carrier such that a first side of the semiconductor die faces the carrier, and a contact clip arranged over a second side of the semiconductor die, opposite the first side, the contact clip comprising a lowered part, wherein the lowered part is arranged in the recess.

Various aspects pertain to a method for fabricating a semiconductor package, the method comprising: providing a carrier, the carrier comprising a recess, arranging a semiconductor die on the carrier such that a first side of the semiconductor die faces the carrier, arranging a contact clip over a second side of the semiconductor die, opposite the first side, the contact clip comprising a lowered part, wherein the contact clip is arranged on the semiconductor die such that the lowered part of the contact clip is arranged in the recess.

### BRIEF DESCRIPTION OF THE DRAWINGS

The accompanying drawings illustrate examples and together with the description serve to explain principles of the disclosure. Other examples and many of the intended advantages of the disclosure will be readily appreciated as they become better understood by reference to the following detailed description. The elements of the drawings are not necessarily to scale relative to each other. Identical reference numerals designate corresponding similar parts.

FIG. 1 shows a sectional view of a semiconductor package comprising a contact clip with a lowered part, wherein the lowered part is arranged at least partially in a recess of a carrier.

FIGS. 2A and 2B show sectional views of further semiconductor packages having lowered parts with different configurations.

FIGS. 3A and 3B show a top down view and a detail view of a further semiconductor package.

FIGS. 4A and 4B show top down views of further semiconductor packages, wherein the lowered part of the contact clip is arranged in a different manner.

FIG. 5 shows a top down view of a leadframe comprising a plurality of contact clips with lowered parts.

FIGS. 6A to 6E show sectional views of a semiconductor package in various stages of fabrication according to an exemplary method for fabricating a semiconductor package.

FIGS. 7A and 7B show top down views of two semiconductor packages comprising a contact clip with lowered parts and a plurality of semiconductor dies electrically coupled by the contact clip.

FIG. 8 is a flow chart of a method for fabricating a semiconductor package.

### DETAILED DESCRIPTION

In the following detailed description, reference is made to the accompanying drawings. It may be evident, however, to one skilled in the art that one or more aspects of the disclosure may be practiced with a lesser degree of the specific details. In other instances, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The semiconductor die(s) mentioned further below may be of different types, may be manufactured by different technologies and may include for example integrated electrical circuits, logic integrated circuits, control circuits, microprocessors, AC/DC or DC/DC converter circuits, power MOS transistors, power Schottky diodes, JFETs (Junction Gate Field Effect Transistors), power bipolar transistors, etc. The examples may also use semiconductor dies comprising a vertical transistor structure in which at least one electrical contact pad is arranged on a first main face of the semiconductor die and at least one other electrical contact pad is arranged on a second main face of the semiconductor die opposite to the first main face.

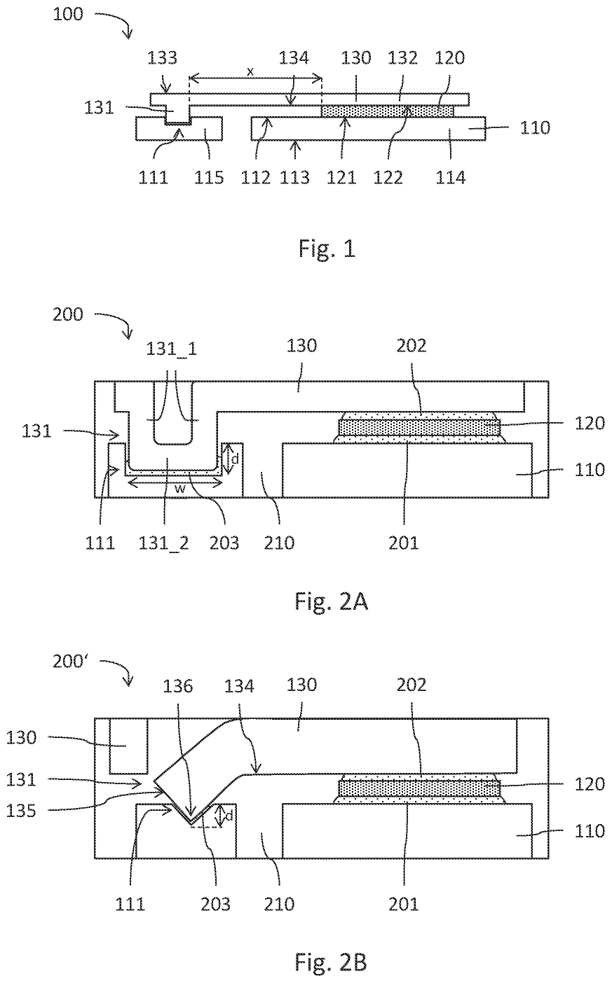

FIG. 1 shows a semiconductor package 100 comprising a carrier 110, a semiconductor die 120 and a contact clip 130. The semiconductor die 120 is arranged on the carrier 110 such that a first side 121 of the semiconductor die 120 faces the carrier 110 and a second side 122 faces away from the carrier 110. The contact clip 130 is arranged over the second side 122 of the semiconductor die 120. The contact clip 130 comprises a lowered part 131 and the carrier 110 comprises a recess 111, wherein the lowered part 131 is arranged in the recess 111 or is arranged at least partially in the recess 111.

The semiconductor package 100 may comprise a single semiconductor die 120 or it may comprise a plurality of semiconductor dies. The semiconductor die(s) of the semiconductor package 100 may for example realize a half-bridge circuit, a power converter circuit, a rectifier circuit, etc. The semiconductor die 120 may be a power semiconductor die configured to operate with a high voltage and/or a high electrical current. The semiconductor package may further comprise one or more logic dies configured to control the semiconductor die(s) 120.

The carrier 110 may comprise or consist of a metal such as Al, Cu or Fe. The carrier 110 may for example be a part of a first leadframe. The carrier 110 may have any suitable thickness perpendicular to the upper and lower sides 112, 113, e.g. a thickness of 200 μm or more, 250 μm or more or 500 μm or more.

According to an example, the semiconductor package 100 comprises several semiconductor dies 120 and several parts of the carrier 110, wherein at least some of the semiconductor dies 120 are arranged on different parts of the carrier 110.

The carrier 110 may comprise an upper side 112 and an opposing lower side 113. The semiconductor die 120 may be arranged on the upper side 112. The semiconductor die 120 may be attached to the upper side 112 by a joint, e.g. by a solder joint, a sintered joint, conductive glue, etc. (not shown in FIG. 1). The semiconductor die 120 may comprise a first power electrode (e.g. a source, drain, emitter or collector electrode) on the first side 121 and the first power electrode may be electrically coupled to the carrier 110.

The recess 111 may be arranged in the upper side 112 of the carrier, laterally besides the semiconductor die 120. In particular, only the lowered part 131 but not the semiconductor die 120 may be arranged in the recess 131. The recess 131 may be laterally spaced apart from the semiconductor die 120 by a distance x. The distance x may e.g. be 1 mm or more, 2 mm or more, 5 mm or more, or 10 mm or more. The lowered part 131 may be coupled to the carrier 110 in the recess 111 by a joint, e.g. a solder joint, a sintered joint or conductive glue.

According to an example, the carrier 110 comprises a first carrier part 114 and a second carrier part 115, wherein the two carrier parts 114, 115 are arranged laterally besides each other. The semiconductor die 120 may be arranged on the first carrier part 114 and the recess may be arranged on the second carrier part 115. The two carrier parts 114, 115 may be electrically insulated from each other, except for a connection via the contact clip 130. The first carrier part 114 may be a die pad. The second carrier part 115 may be a contact, e.g. an external contact of the semiconductor package 100, or the second carrier part 115 may be another die pad within the semiconductor package 100.

The contact clip 130 may e.g. comprise or consist of a metal, for example Al, Cu or Fe. The contact clip 130 may be part of a second leadframe which may be different from the first leadframe. The contact clip 130 may have any suitable thickness, e.g. a thickness of 200 μm or more, 250 μm or more, or 500 μm or more. The thickness of the contact clip 130 may be identical to the thickness of the carrier 110 or it may be different from the thickness of the carrier 110.

The contact clip 130 may be coupled to the second side 122 of the semiconductor die 120, in particular to a second power electrode (e.g. a source, drain, emitter or collector electrode) by a joint, e.g. a solder joint, a sintered joint or conductive glue (not shown in FIG. 1). The contact clip 130 may completely cover the second side 122 or it may only partially cover the second side 122, e.g. no more than 40%, 60% or 80% of the second side 122.

The contact clip 130 may extend laterally beyond the circumference of the semiconductor die 120 in the direction towards the lowered part 131. The contact clip 130 may furthermore extend laterally beyond the circumference in any other direction, e.g. in the opposite direction.

According to an example, the contact clip 130 comprises a central part 132 and the lowered part 131 extends out of the central part 132 towards the carrier 110. The central part 132 may essentially be arranged in a plane above the second side 122 of the semiconductor die 120. The lowered part 131 may extend from a lower side 134 of the central part 132 into the recess, thereby spanning the thickness of the semiconductor die 120 (as well as the thickness of the joints arranged on the first and second sides 121, 122 of the semiconductor die 120).

According to an example, the lower part 131 may be arranged at an angle relative to the central part 132, e.g. an angle in the range of 30° to 90°, e.g. an angle of about 30°, about 45°, about 60°, about 80° or about 90°.

According to an example, the semiconductor die 120 may be a thinned die. The semiconductor die 120 may e.g. have a thickness measured perpendicular to the first and second sides 121, 122 of less than 50 μm, about 50 μm or more, about 100 μm or more, 200 μm or more or 500 μm or more. The semiconductor die 120 may comprise a control electrode (e.g. a gate electrode) which may e.g. be arranged on the second side 122 in such a position that it is not covered by the contact clip 130. The semiconductor package 100 may comprise an electrical connector like a bond wire coupled to the control electrode.

The semiconductor package 100 may comprise an encapsulant encapsulating the semiconductor die 120. The encapsulant may comprise a polymer, e.g. in the form of a molded body. According to an example, the carrier 110 and/or the contact clip 130 may be at least partially exposed from the encapsulant. For example, the lower side 113 of the carrier and/or an upper side 133 of the contact clip may be exposed from the encapsulant. The lower side 113 and/or the upper side 133 may be coplanar with respective external surfaces of the encapsulant. The encapsulant may fill a space between the lower side 134 of the contact clip 130 and the carrier 110. The encapsulant may fill the gap between the first and second carrier parts 114, 115.

FIGS. 2A and 2B show further semiconductor packages 200 and 200′, respectively, which may be similar to or identical with the semiconductor package 100.

As shown in FIG. 2A, in the semiconductor package 200 the contact clip 130 comprises a lowered part 131 having a U-shape as seen in a plane perpendicular to the lower and upper sides 133, 434. The U-shaped lowered part 131 may comprise side walls 131_1 and a bottom wall 131_2. The side walls 131_1 and the bottom wall 131_2 may be arranged essentially perpendicular to each other. However, it is also possible that the side walls 131_1 and the bottom wall 131_2 are arranged in another angle than 90°, e.g. an angle of about 80°, about 70°, about 60° or about 45°. According to an example, the lowered part 131 does not comprise the bottom wall 131_2 but instead only comprises the side walls 131_1 arranged in an angle smaller than 90° (in other words, the lowered part 131 may have a V-shape).

The bottom wall 131_2 may for example have a width w of about 200 μm or more, 300 μm or more or 500 μm or more. The recess 111 may have an identical width or a width that is only slightly bigger. The width of the lowered part 131 and the width of the recess 111 may be matched to each other such that the lowered part 131 tightly fits into the recess 111. The recess may have any suitable depth d, e.g. a depth d of 50 μm or more, 100 μm or more, 150 μm or more or 200 μm or more. The depth d may be about 20% of the thickness of the carrier 110 (measured perpendicular to the upper and lower sides 112, 113), about 40%, about 60% or about 80%.

According to an example, the U-shaped lowered part 131 of the semiconductor package 200 may be fabricated by coining or by stamping the contact clip 130. This coining or stamping may e.g. be done prior to singulating the contact clip 130 from the second leadframe.

The semiconductor package 200 may comprise a first joint 201 coupling the semiconductor die 120 to the carrier 110, a second joint 202 coupling the contact clip 130 to the semiconductor die and a third joint 203 coupling the lowered part 131 of the contact clip 130 to the recess 111. The first, second and third joints may for example comprise solder joints, sintered joints or conductive glue.

The third joint 203 may be arranged partially or completely within the recess 111. The third joint 203 may e.g. be arranged partially or completely below the bottom wall 131_2.

The first, second and third joints 201, 202, 203 may e.g. be reflow solder joints. During reflow soldering the contact clip 130 may be held in place by the tight fit between the lowered part 131 and the recess 111 and may thereby be prevented from drifting out of position.

According to an example, the semiconductor package 200 further comprises an encapsulant 210. The encapsulant 210 may partially fill the recess 111. However, it is also possible that no material or almost no material of the encapsulant 210 is arranged within the recess 111. The semiconductor package 200 may be a surface mounted device (SMD), wherein the lower side 113 of the carrier 110 is e.g. arranged on a board. The upper side 133 of the contact clip 130 may e.g. be configured to have a heatsink attached to it.

FIG. 2B shows the semiconductor package 200′ which may be identical with the semiconductor package 200 except that the lowered part 131 of the semiconductor package 200′ comprises a pointed edge 136 pointing towards the carrier 110. In this regard, “pointing towards the carrier 110” may mean that the pointed edge 136, the distal end face 135 and the lower side 134 may form a “wedge” that points towards the carrier 110. The pointed edge 136 may be arranged at the bottom of the recess 111. The recess 111 of the semiconductor package 200′ may have a corresponding wedge shape. The lowered part 131 may be arranged at any suitable position within the contact clip 130, for example close to a lateral end or directly at a lateral end of the contact clip 130.

According to an example, the lowered part 131 may be a contact finger that is bent down towards the carrier 110. The lowered part 131 may comprise a distal end face 135. The distal end face 135 and the parts of the upper and lower sides 133, 134 that are comprised in the lowered part 131 may be arranged perpendicular to each other. The distal end face 135 may be a cut surface at which the contact clip 130 has been cut during fabrication of the lowered part 131. The pointed edge 136 may be the edge between the distal end face 135 and the lower side 134 of the contact clip 130.

According to an example, the distal end face 135 and the upper side 112 of the carrier 110 are arranged at an angle in the range of 30° to 80° with respect to each other, for example at an angle of about 45°.

According to an example, the totality of the lowered part 131 (i.e. the whole part of the contact clip that is arranged below the plane comprising the central part 132) has a triangular shape. According to another example, only an end region of the lowered part 131, wherein the end region is at least partially arranged within the recess 111, has a triangular shape.

The recess 111 of the semiconductor package 200′ may have the triangular shape or wedge shape. In particular, the recess 111 may be tapered towards its bottom. The recess 111 and the lowered part 131 may have matching shapes and the orientations of the shapes may match as well. The recess 111 may have slightly larger dimensions than the lowered part 131 such that the third joint 203 can be arranged within the recess 111, between the lowered part 131 and the carrier 110.

However, the dimensions of the lowered part 131 and the recess 111 may be matched such that a tight fit between the two is ensured as explained further above with reference to semiconductor package 200.

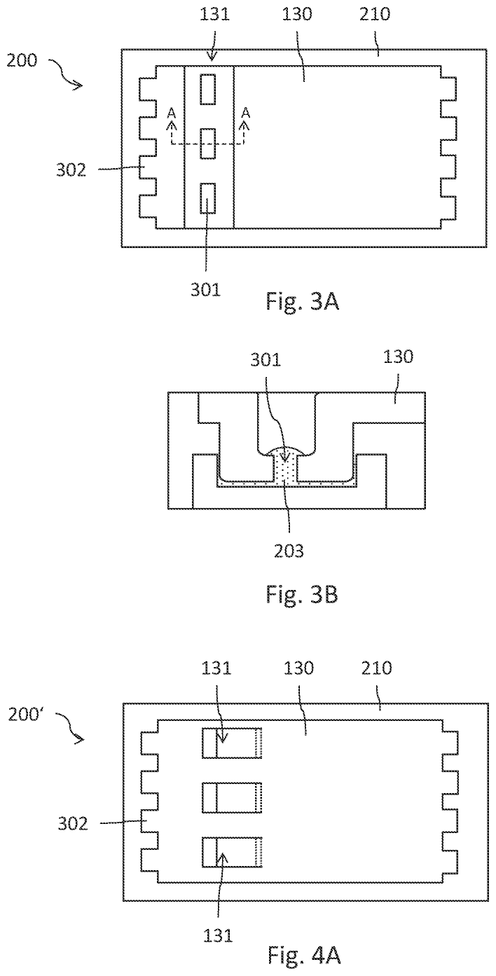

FIG. 3A shows an example of the semiconductor package 200 in a top down view from above the upper side 133 of the contact clip 130. In the example shown in FIG. 3A, the contact clip 130 comprises holes 301 in the lowered part 131. The contact clip 130 may comprise any suitable number of holes 301. According to another example of the semiconductor package 200, the contact clip 130 does not comprise the holes 301.

According to an example, the contact clip 130 may further comprise protrusions 302 which may e.g. be arranged at one or more lateral sides of the contact clip 130, for example at opposing lateral sides. The protrusions 302 may be cut tie bars used to couple the contact clip 130 to the second leadframe during fabrication of the semiconductor package 200.

FIG. 3B shows a detail view of the semiconductor package 200 along the line A-A in FIG. 3A.

The one or more holes 301 may e.g. be arranged in the bottom wall 131_2 of the lowered part 131. The material of the third joint 203 may at least partially fill the one or more holes 301. In particular, the material of the third joint 203 may fully extend through the one or more holes 301 and it may also be arranged above the one or more holes 301 within the recess 111. Having the material of the third joint 203 arranged within and possible above the one or more holes 301 may e.g. improve the coupling strength of the third joint 203 as well as the mechanical and electrical reliability of the semiconductor package 200.

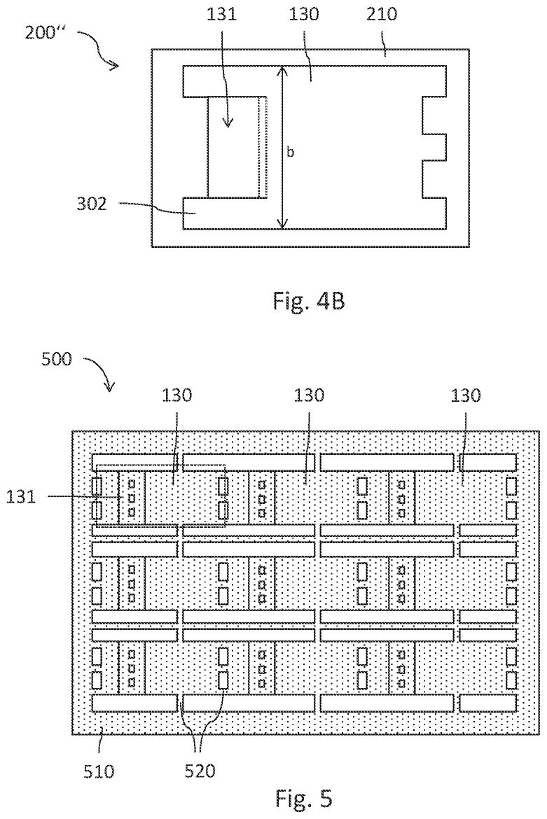

FIG. 4A shows an example of the semiconductor package 200′ in a top down view from above the upper side 133 of the contact clip 130. As shown in FIG. 4A, the contact clip 130 may comprise a plurality of lowered parts 131. Each lowered part 131 may be an individual contact finger of the contact clip 130.

The lowered parts 131 may e.g. be arranged in a row as shown in FIG. 4A. However, it is also possible that the lowered parts 131 are arranged in any other suitable configuration. All lowered parts 131 may be coupled to the same carrier part or individual lowered parts 131 may be coupled to different carrier parts. Furthermore, the carrier 110 may comprise a separate recess 111 for each individual lowered part 131 or at least some of the lowered parts 131 may be arranged in a common recess 111.

FIG. 4B shows a top down view of a semiconductor package 200″ which may be identical with the semiconductor package 200′ except for the following differences.

In the semiconductor package 200″ the contact clip 130 comprises a single lowered part 131. The lowered part 131 may essentially span the whole breadth b of the contact clip 130. It is also possible that the lowered part 131 spans only part of the whole breadth b. For example, the contact clip 130 may comprise one or more protrusions 302, wherein the lowered part 131 spans the breadth b except for those parts comprising the protrusions 302.

In semiconductor package 200″ of FIG. 4B the lowered part 131 forms part of an edge of the contact clip 130, whereas in semiconductor package 200′ of FIG. 4A the lowered parts 131 are arranged in the interior of the contact clip 130 and do not form part of an edge. However, either arrangement may be used in each case.

FIG. 5 shows a top down view of an example of a second leadframe 500 comprising a plurality of contact clips 130. The second leadframe 500 may comprise an outer frame 510, wherein the plurality of contact clips 130 is arranged within the outer frame 510. The plurality of contact clips 130 may be connected to the outer frame 510 and/or to each other by tie bars 520. Singulating a contact clip 130 from the second leadframe 500 may comprise cutting the tie bars 520 along the circumference of the respective contact clip 130 (e.g. along the dashed lines in FIG. 5).

The example of FIG. 5 shows the plurality of contact clips 130 to be arranged in a two dimensional array. According to another example, the plurality of contact clips 130 may be arranged in a single stripe or in any other suitable arrangement. Furthermore, the contact clips 130 of the second leadframe 500 may have any suitable shape and in particular need not necessarily be rectangular as shown in FIG. 5. For example, the contact clips 130 may essentially have an L-shape as seen from above and may be configured to electrically couple several semiconductor dies 120 of a semiconductor package.

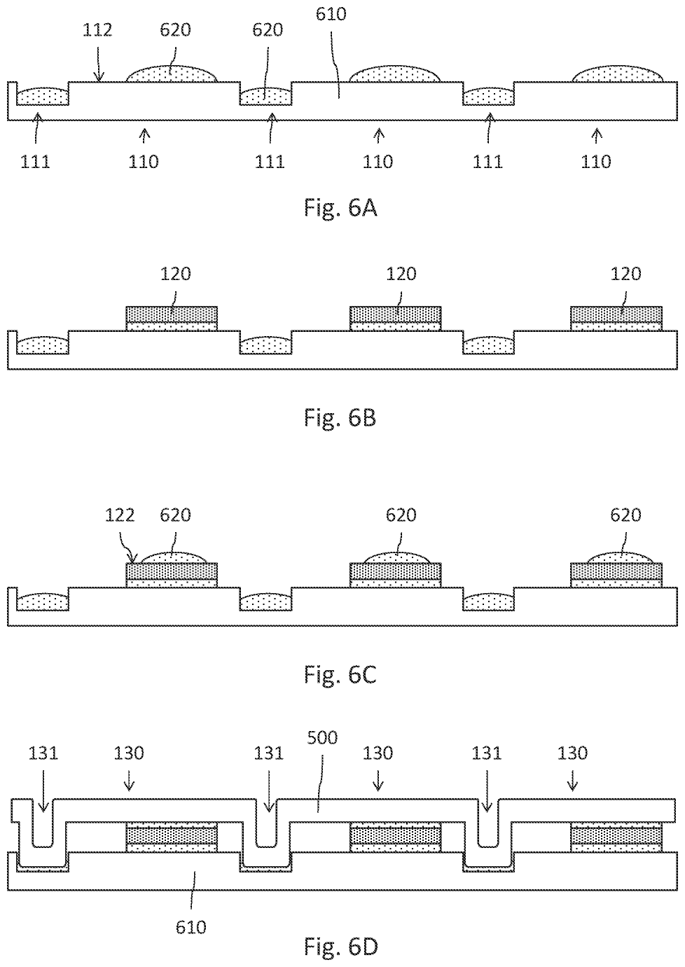

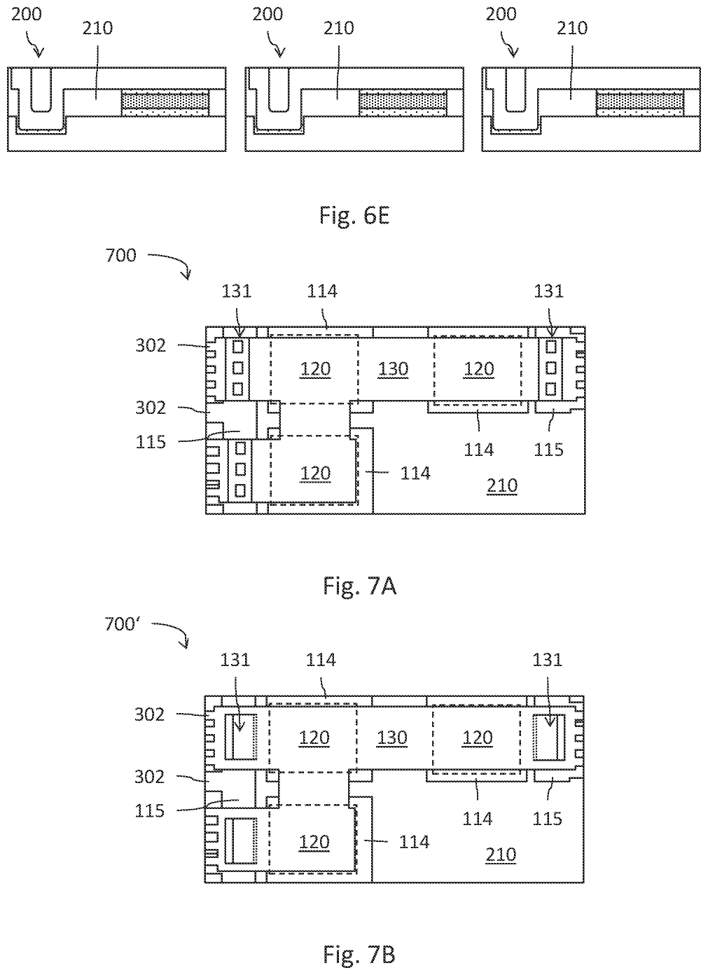

The second leadframe 500 may be configured such that the plurality of contact clips 130 can be arranged on a plurality of corresponding carriers 110 (which may e.g. be part of a first leadframe) while the contact clips 130 are still part of the second leadframe 500. This may comprise arranging the second leadframe 500 over the first leadframe as shown in FIG. 6D. In other words, the second leadframe 500 may be configured to enable connecting the plurality of contact clips 130 to the plurality of respective carriers 110 in a single batch process. Such a batch process may e.g. be faster than a serial pick-and-place process that comprises placing each contact clip 130 onto the respective carrier 110 and semiconductor die 120 individually. Such a batch process may therefore help with saving fabrication time and fabrication costs of semiconductor packages.

With reference to FIGS. 6A to 6E the semiconductor package 200 is shown in various stages of fabrication according to an exemplary method for fabricating a semiconductor package. A similar method may be used for fabricating the semiconductor packages 100, 200′ and 200″.

As shown in FIG. 6A, a first leadframe 610 may be provided, the first leadframe 610 comprising a plurality of carriers 110, wherein each carrier 110 comprises at least one recess 111. According to an example, the recesses 111 are fabricated by coining or stamping or etching the first leadframe 610. The recesses 111 may in particular be fabricated before the carriers 110 are singulated from the first leadframe 610.

Furthermore, deposits of connecting material 620 may be deposited on the first leadframe 610, e.g. by using a dispensing process. The connecting material 620 may e.g. be solder material, sintering material or conductive glue. The deposits of connecting material 620 may be arranged on the upper side 112 of the carriers 110 and in the recesses 111. It is also possible that the connecting material 620 may be deposited in the recesses 111 at a later stage.

As shown in FIG. 6B, a plurality of semiconductor dies 120 may be arranged over the first leadframe 610. For example, the semiconductor dies 110 may be placed onto the deposits of connecting material 620 arranged on the upper side 112. Placing the semiconductor dies 110 onto the deposits of connecting material 620 may e.g. be done by a serial pick-and-place process.

According to an example, the connecting material 620 is only deposited in the recesses 111 after the semiconductor dies 110 have been arranged over the first leadframe 610.

According to an example, the connecting material 620 is a solder material and the semiconductor dies 120 are soldered onto the first leadframe 610 in this stage of fabrication.

As shown in FIG. 6C, the connecting material 620 may be deposited on the second side 122 of the semiconductor dies 120. It is also possible that the connecting material 620 is deposited in the recesses 111 at this stage.

As shown in FIG. 6D, the second leadframe 500 may be arranged over the first leadframe 610 such that each lowered part 131 is arranged in a respective recess 111. Furthermore, the second leadframe 500 may be attached to the first leadframe 610 and to the semiconductor dies 120 by the connecting material 620. In the case that the connecting material 620 is a solder material, this may e.g. entail using a reflow soldering process.

The exemplary method for attaching the contact clips 130 to the carriers 110 shown in FIG. 6D may be termed a batch process, since a plurality of contact clips 130 is arranged over and attached to a plurality of carriers 110 in parallel. Using such a batch process may reduce fabrication time and fabrication costs compared to using a sequential pick-and-place process.

As shown in FIG. 6E, individual semiconductor packages 200 are singulated by cutting the first and second leadframes 610, 500. Furthermore, fabricating the semiconductor package 200 may comprise fabricating the encapsulant 210, e.g. by using a molding process. The encapsulant 210 may be fabricated prior to cutting the first and second leadframes 610, 500 or after cutting the first and second leadframes 610, 500.

The method for fabricating the semiconductor package 200 shown in FIGS. 6A-6E comprises the use of stacked leadframes 610, 500. For this reason, the semiconductor package 200 may comprise stacked tie bars or protrusions belonging to the first leadframe 610 and the second leadframe 500, respectively. According to an example, the stacked tie bars are exposed from the encapsulant 210 at lateral sides of the semiconductor package 200.

FIG. 7A shows a top down view of a semiconductor package 700 which may be similar to or identical with the semiconductor packages 100, 200, 200′ and 200″, except for the differences described in the following.

The semiconductor package 700 comprises several semiconductor dies 120, e.g. three semiconductor dies 120 (in the top down view of FIG. 7A the semiconductor dies 120 are covered by the contact clip 130 and are therefore indicated by dashed lines). The semiconductor dies 120 are arranged on respective first carrier parts 114. At least some of the semiconductor dies 120 are electrically coupled to each other by the contact clip 130. In the example shown in FIG. 7A, the contact clip 130 electrically couples all three of the semiconductor dies 120.

The contact clip 130 of the semiconductor package 700 may comprise one or more lowered parts 131 which may be arranged within respective recesses 111 (not shown in FIG. 7A). The lowered parts 131 may e.g. comprise the U-shaped cross section described with regard to FIG. 2A. The recesses 111 may e.g. be arranged in respective second carrier parts 115. The second carrier parts 115 may e.g. be external contacts of the semiconductor package 700. The semiconductor package may comprise the encapsulant 210. The external contacts and possibly also the contact clip 130 may be exposed from the encapsulant 210.

The contact clip 130 as well as the second carrier parts 115 may comprise the protrusions 320 (i.e. tie bar remnants). The protrusions of the contact clip 130 may be arranged in a first plane, the protrusions of the carrier 110 may be arranged in a second plane and the first plane may be arranged above the second plane.

FIG. 7B shows a top down view of a semiconductor package 700′ which may be similar to or identical with the semiconductor package 700, except for the differences described in the following.

In the semiconductor package 700′ the lowered part 131 of the contact clip 130 comprises the pointed edge 136 pointing towards the carrier 110 as described with regard to FIG. 2B. In FIGS. 7A and 7B the contact clips 130 of the semiconductor packages 700 and 700′ are shown to comprise several lowered parts 131. However, it is also possible that the contact clips 130 each only comprise a single lowered part 131.

Fabricating the semiconductor packages 700 and 700′ may for example comprise arranging a second leadframe comprising a plurality of contact clips 130 (like the exemplary second leadframe 500) over a first leadframe comprising a plurality of carriers 110 in a single batch process step. The lowered parts 131 of the plurality of contact clips 130 may interact with the recesses 111 of the plurality of carriers 110 and may help with properly aligning the first and second leadframes relative to each other. The lowered parts 131 of the individual contact clips 130 may cooperate to align the first and second leadframes, which may reduce the necessary number of lowered parts 131 per contact clip 130.

In the above-described way, the plurality of contact clips 130 may be coupled to the plurality of carriers 110 (and to semiconductor dies 120 arranged on the carriers 110) in order to fabricate a plurality of semiconductor packages 700 or 700′ in a batch process. The contact clips 130 and carriers 110 may be singulated from the first and second leadframes respectively in a later process step.

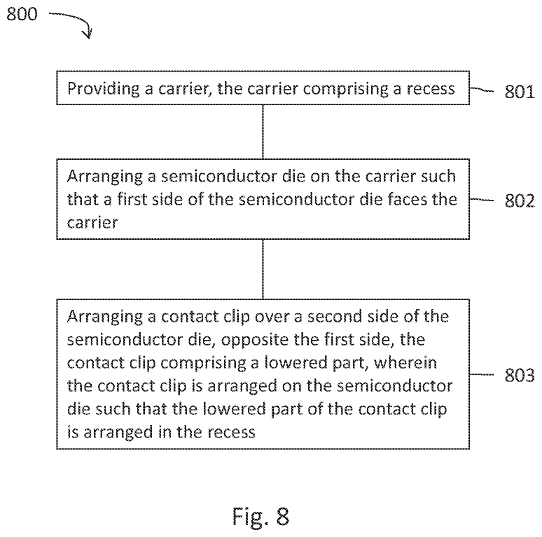

FIG. 8 is a flow chart of a method 800 for fabricating a semiconductor package. The method 800 may for example be used to fabricate the semiconductor packages 100, 200, 200′, 200″ and 700.

Method 800 comprises at 801 an act of providing a carrier, the carrier comprising a recess, at 802 an act of arranging a semiconductor die on the carrier such that a first side of the semiconductor die faces the carrier, and at 803 an act of arranging a contact clip over a second side of the semiconductor die, opposite the first side, the contact clip comprising a lowered part, wherein the contact clip is arranged on the semiconductor die such that the lowered part of the contact clip is arranged in the recess.

According to an example of the method 800, the carrier is part of a first leadframe. The method 800 may further comprise singulating the carrier from the first leadframe after the contact clip has already been arranged on the semiconductor die.

According to an example of the method 800, the contact clip is part of a second leadframe comprising a plurality of contact clips and is arranged over the semiconductor die in a batch process. The method 800 may further comprise singulating the contact clip from the second leadframe after it has already been arranged on the semiconductor die.

In the following, the semiconductor package and the method for fabricating a semiconductor package are further described using specific examples.

Example 1 is a semiconductor package, comprising: a carrier comprising a recess, a semiconductor die arranged on the carrier such that a first side of the semiconductor die faces the carrier, a contact clip arranged over a second side of the semiconductor die, opposite the first side, the contact clip comprising a lowered part, wherein the lowered part is arranged in the recess.

Example 2 is the semiconductor package of example 1, wherein the lowered part is arranged at a first lateral end of the contact clip.

Example 3 is the semiconductor package of example 1 or claim 2, wherein the lowered part is a coined or stamped part.

Example 4 is the semiconductor package of one of the preceding examples, further comprising: a solder joint arranged in the recess and coupling the contact clip to the carrier.

Example 5 is the semiconductor package of one of the preceding examples, wherein the contact clip has a central part over the second side of the semiconductor die, and the lowered part bends downwards towards the carrier from the central part.

Example 6 is the semiconductor package according to example 5, wherein the lowered part comprises a pointed edge facing the carrier, the pointed edge being arranged at the bottom of the recess.

Example 7 is the semiconductor package of example 5 or 6, wherein the lowered part comprises at least one finger bent down by an angle of 30° to 80° and extending from the central part of the contact clip.

Example 8 is the semiconductor package of one of examples 1 to 5, wherein the lowered part has a U-shaped cross section.

Example 9 is the semiconductor package of example 8, wherein the contact clip comprises one or more holes arranged in the lowered part.

Example 10 is the semiconductor package of example 9, wherein solder material extends through the one or more holes.

Example 11 is the semiconductor package of one of the preceding examples, wherein the lowered part and the recess have congruent cross sections.

Example 12 is the semiconductor package of one of the preceding examples, wherein the contact clip is arranged on a plurality of semiconductor dies on the carrier.

Example 13 is a method for fabricating a semiconductor package, the method comprising: providing a carrier, the carrier comprising a recess, arranging a semiconductor die on the carrier such that a first side of the semiconductor die faces the carrier, arranging a contact clip over a second side of the semiconductor die, opposite the first side, the contact clip comprising a lowered part, wherein the contact clip is arranged on the semiconductor die such that the lowered part of the contact clip is arranged in the recess.

Example 14 is the method of example 13, further comprising: depositing a first solder deposit on the carrier, depositing a second solder deposit on the second side of the semiconductor die, and depositing a third solder deposit in the recess.

Example 15 is the method of example 14, further comprising: reflow soldering the first, second and third solder deposits, wherein the contact clip is held in place during the reflow soldering by the lowered part interlocking with the recess.

Example 16 is the method of one of examples 13 to 15, further comprising: coining or stamping the contact clip to fabricate the lowered part.

Example 17 is the method of one of examples 13 to 16, wherein the carrier is part of a first leadframe and wherein the method further comprises: singulating the carrier from the first leadframe after the contact clip has been arranged on the semiconductor die.

Example 18 is the method of one of examples 13 to 17, further comprising: coining or stamping the carrier to fabricate the recess.

Example 19 is the method of one of examples 13 to 18, wherein the contact clip is part of a second leadframe comprising a plurality of contact clips and wherein the method further comprises: singulating the contact clip from the second leadframe after it has been arranged on the semiconductor die.

Example 20 is the method of one of examples 13 to 19, wherein the lowered part has a U-shaped cross section or a pointed edge pointing towards the carrier.

Example 21 is the method of one of examples 13 to 20, further comprising: encapsulating the semiconductor die, at least part of the contact clip and at least part of the carrier with a molded body.

Example 22 is an apparatus comprising means for performing the method of anyone of examples 13 to 21.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A semiconductor package, comprising:
a carrier comprising a recess;
a semiconductor die arranged on the carrier such that a first side of the semiconductor die faces the carrier; and
a contact clip arranged over a second side of the semiconductor die, opposite the first side, the contact clip comprising a lowered part,
wherein the lowered part is arranged in the recess,
wherein the contact clip further comprises a central part over the second side of the semiconductor die,
wherein the lowered part bends downwards towards the carrier from the central part.

2. The semiconductor package of claim 1, wherein the lowered part comprises a pointed edge pointing towards the carrier, and wherein the pointed edge is arranged at a bottom of the recess.

3. The semiconductor package of claim 1, wherein the lowered part comprises at least one finger bent down by an angle of 30° to 80° and extending from the central part of the contact clip.

4. The semiconductor package of claim 1, wherein the lowered part is arranged at a first lateral end of the contact clip.

5. The semiconductor package of claim 1, wherein the lowered part is a coined or stamped part.

6. The semiconductor package of claim 1, further comprising:
a solder joint arranged in the recess and coupling the contact clip to the carrier.

7. The semiconductor package of claim 1, wherein the contact clip is arranged on a plurality of semiconductor dies on the carrier.

8. The semiconductor package of claim 1, wherein the lowered part and the recess have congruent cross sections.

9. A semiconductor package, comprising:
a carrier comprising a recess;
a semiconductor die arranged on the carrier such that a first side of the semiconductor die faces the carrier; and
a contact clip arranged over a second side of the semiconductor die, opposite the first side, the contact clip comprising a lowered part,
wherein the lowered part is arranged in the recess,
wherein the contact clip further comprises one or more holes arranged in the lowered part, and
wherein solder material extends through the one or more holes.

10. The semiconductor package of claim 9, wherein the lowered part has a U-shaped cross section.

11. The semiconductor package of claim 9, wherein the lowered part and the recess have congruent cross sections.

12. The semiconductor package of claim 9, wherein the contact clip is arranged on a plurality of semiconductor dies on the carrier.

13. The semiconductor package of claim 9, wherein the lowered part is a coined or stamped part.

14. A method for fabricating a semiconductor package, the method comprising:
providing a carrier, the carrier comprising a recess;
arranging a semiconductor die on the carrier such that a first side of the semiconductor die faces the carrier; and
arranging a contact clip over a second side of the semiconductor die, opposite the first side, the contact clip comprising a lowered part,
wherein the contact clip is arranged on the semiconductor die such that the lowered part of the contact clip is arranged in the recess.

15. The method of claim 14, further comprising:
depositing a first solder deposit on the carrier;
depositing a second solder deposit on the second side of the semiconductor die; and
depositing a third solder deposit in the recess.

16. The method of claim 15, further comprising:
reflow soldering the first, second and third solder deposits, wherein the contact clip is held in place during the reflow soldering by the lowered part interlocking with the recess.

17. The method of claim 14, further comprising:
coining or stamping the contact clip to fabricate the lowered part.

18. The method of claim 14, wherein the carrier is part of a first leadframe, the method further comprising:
singulating the carrier from the first leadframe after the contact clip has been arranged on the semiconductor die.

19. The method of claim 14, further comprising:
coining or stamping the carrier to fabricate the recess.

20. The method of claim 14, wherein the contact clip is part of a second leadframe comprising a plurality of contact clips, the method further comprising:
singulating the contact clip from the second leadframe after the contact clip has been arranged on the semiconductor die.

21. The method of claim 14, wherein the lowered part has a U-shaped cross section or a pointed edge pointing towards the carrier.

22. The method of claim 14, further comprising:
encapsulating the semiconductor die, at least part of the contact clip and at least part of the carrier with a molded body.
